(19) United States
(12) Patent Application Publication
(10) Pub. No.: US 2001/0045594 A1
(43) Pub. Date: Nov. 29, 2001

(54) ONE TIME PROGRAMMABLE READ ONLY MEMORY

(76) Inventor: KUANG-YEH CHANG, TAIPEI (TW)

Correspondence Address: J. C. Patents, Inc., 4 Venture, Suite 250, Irvine, CA, 92618, US

(21) Appl. No.: 09/239,033

(22) Filed: Jan. 27, 1999

(51) Int. Cl. H01L 29/76; H01L 29/94

(52) U.S. Cl. 257/315; 257/390; 257/314; 257/317

(57) ABSTRACT

Provided is a one time programmable read only memory, which includes a floating gate, an inter-metal dielectric layer and a control gate stacked on each other on a substrate. Furthermore, ion-implanted regions are formed in the substrate on both sides of the stacked gate structure, and are covered by metal silicide layers. The inter-metal dielectric layer comprises an oxide layer and a silicon nitride layer, wherein the oxide layer covers the floating gate, and the silicon nitride layer further covers the floating gate and the metal silicide layer. The control gate covers the silicon nitride layer. Furthermore, the one time programmable read only memory of the invention not only can reduce the electrical resistance of bit lines and enhance its own performance, but also has a small size and a greater planarity due to an absence of field oxide layers and contact windows formed thereon and therein.

### BACKGROUND OF THE INVENTION

1. Field of the Invention

The invention relates to a memory, and in particular to a one time programmable read only memory (OTP-ROM).

2. Description of the Related Art

In line with increasingly stronger functions of a microprocessor, programs and their executions become greater and more complicated. Under this condition, memory with a great amount of storage capacity is required. For this purpose, how to manufacture memory having a great amount of storage capacity and a low cost is a critical issue for semiconductor manufacturers. Based on read/write functions, memory can be generally classified into read only memory (ROM) and random access memory (RAM). Read only memory can only execute a “read” operation while random access memory can execute both “read” and “write” operations. According to the way that data are stored, read only memory can be further divided into mask ROM, programmable ROM, erasable programmable ROM (EPROM), electrically erasable programmable ROM, etc. Moreover, according to the way that data are accessed, random access memory can be finely divided into static RAM and dynamic RAM.

It well known that read only memory which has been widely applied in digital equipment units, such as mini computers and microprocessor systems, is used to store system data, such as BIOS. The ROM manufacturing process is substantially more complicated. In other words, it is necessary to take much more time to perform a great number of steps and material processing. Therefore, clients generally provide program data to memory manufacturers. During ROM manufacturing, the program data are recorded into manufactured ROMs.

Except for various program data recorded in manufactured ROMs during programming, manufactured ROMs all have the same structure. Typically, ROM manufacturing process stops before programming. Then, incomplete ROMs are stored until specific program data are received from clients. Once the program data are received, masks are prepared to perform the programming. Subsequently, the ROMs are completely manufactured and delivered to the clients. Usually, the post-programming ROM manufacturing process is adopted by semiconductor manufacturers.

In a common ROM. channel transistors serve as memory cells. During programming, channel regions included in the memory cells are selectively implanted with a dopant, thereby changing the threshold voltages thereof to turn on/off the memory cells. As to the structure of a manufactured ROM, polysilicon word lines (WL) perpendicularly cross through bit lines (BL). Moreover, the channel regions of the memory cells are formed between the word lines and the bit lines. Digital data stored in each channel region are determined by whether or not the channel region is implanted.

FIG. 1 is a schematic, top view showing a conventional, programmable read only memory. FIG. 2 is a schematic, cross-sectional view of FIG. 1 along a dashed line I-I. FIG. 3 is a schematic, cross-sectional view of FIG. 1 along a dashed line II-II. A method for manufacturing the conventional programmable read only memory is described hereinafter.

Referring to FIGS. 1, 2 and 3, a substrate 10 is provided. A pad oxide layer (not shown) is formed on the substrate 10 by thermal oxidation. Field oxide layers 14 are formed by, for example. LOCOS, to define active areas. Then, the pad oxide layer is removed by, for example, wet etching. An oxide layer 12 is formed on the surface of the active areas by, for example, thermal oxidation. A polysilicon layer is formed over the substrate, including on the oxide layer 12 by, for example, low pressure chemical vapor deposition. Then, the polysilicon layer is patterned by photolithography and etching to form a first polysilicon layer 16.

Next, an inter-poly dielectric layer is formed on the polysilicon layer 16 by, for example, low pressure chemical vapor deposition. Another polysilicon layer is formed on the inter-poly dielectric layer by, for example, low pressure chemical vapor deposition. The other polysilicon layer and the inter-polysilicon dielectric layer are patterned by photolithography and etching, thereby forming a second polysilicon layer 20 and a remaining inter-polysilicon dielectric layer 18.

Using the second polysilicon layer 20 as a mask, ion implantation is performed to form ion-implanted regions 22 with a heavy concentration of ions by using the second polysilicon layer 20 as a mask. A dielectric layer 24 is formed over the substrate 10 by, for example, low pressure chemical vapor deposition. Furthermore, a contact window 26 is formed in the dielectric layer 24 by photolithography and etching. A metal layer 28, serving as a bit line, is formed in the contact window 26 by, for example, low pressure chemical vapor deposition, and contacts with the ion-implanted region 22. Subsequent processes for further completely manufacturing the programmable ROM are well known by those skilled in the art, and will not be described here.

The manufactured ROM cannot be further shrunk in size due to the limitation on the size of the contact window 26. Additionally, since the field oxide layers are formed, the manufactured ROM has a limitation to miniaturization and a poor planarity. If it is necessary to pattern the uneven structure by, for example, dry etching, an uneven etching problem occurs resulting in an inability to properly control etching time because the etched thicknesses are not uniform. Moreover, since the contact window is filled with the metal layer serving as a bit line, it cannot prevent reflection interference caused by the metal layer.

In a method for manufacturing another conventional programmable read only memory, buried bit lines are formed under field oxide layers for the purpose of miniaturization. However, due to the existence of the field oxide layers, the conventional programmable ROM has a limitation to its miniaturization as well as a poor planarity. Also, the bit lines have a higher electrical resistance, because they are formed under the field oxide layers. Moreover, the buried bit lines positioned under the field oxide layers cannot be formed by a self-aligned method.

### SUMMARY OF THE INVENTION

In view of the above, an object of the invention is to provide a one time programmable read only memory for resolving the disadvantages of the prior read only memory.

To achieve the above-stated object, the one time programmable read only memory includes a control gate, an inter-metal dielectric layer and a floating gate stacked on each other on a substrate. Ion-implanted regions are formed in the substrate on both sides of the stacked gate structure. Metal silicide layers are formed on the ion-implanted regions. Furthermore, the inter-metal dielectric layer includes an oxide layer and a silicon nitride layer, wherein the oxide layer covers the floating gate. The silicon nitride layer further covers the floating gate and the metal silicide layers. The control gate covers the silicon nitride layer included in the inter-metal dielectric layer.

A feature of the one time programmable read only memory of the invention is that the ion-implanted regions, serving as a buried bit line, are formed by a self-aligned method without use of an additional mask or the formations of contact windows and metal layers therein. Therefore, there is no problem of reflection interference. Additionally, the contact resistance of the bit line can be reduced to approximately 1/10-1/100 unnecessary to form field oxide layers, the one time programmable read only memory manufactured according to the invention can have a better planarity and a small size.

### BRIEF DESCRIPTION OF THE DRAWINGS

The invention will become more fully understood from the detailed description given hereinbelow and the accompanying drawings which are given by way of illustration only, and thus do not limit the present invention, and wherein:

FIG. 1 is a schematic, top view showing a conventional programmable read only memory;

FIG. 2 is a schematic. cross-sectional view of FIG. 1 along a dashed line I-I;

FIG. 3 is a schematic, cross-sectional view of FIG. 1 along a dashed line II-II;

FIG. 4 is a schematic, top view showing a one time programmable read only memory according to a preferred embodiment of the invention;

FIGS. 5A-5E are schematic, cross-sectional views showing a method for manufacturing the one time programmable read only memory of FIG. 4 along a dashed line III-III; and

FIG. 6 is a schematic, cross-sectional view of FIG. 4 along a dashed line IV-IV, corresponding to FIG. 5E.

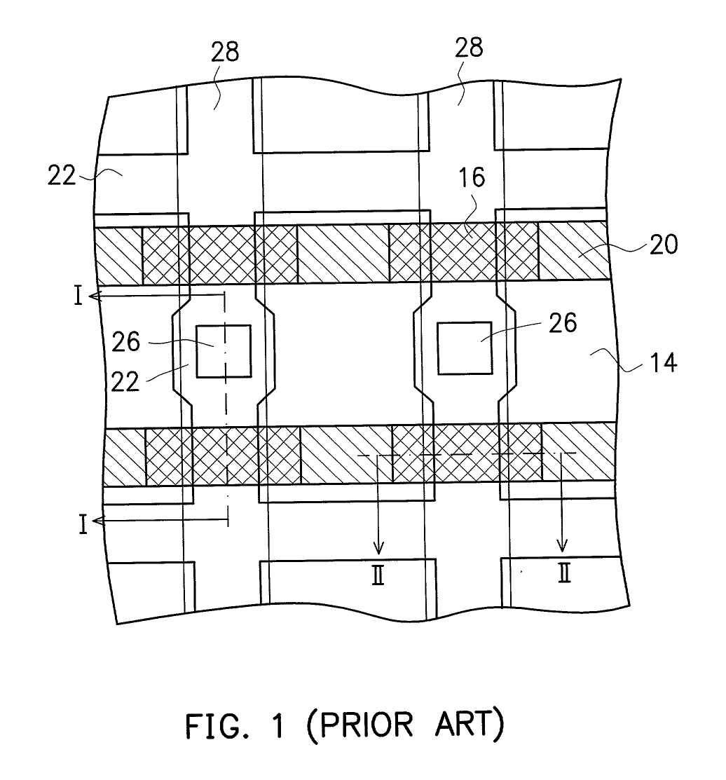

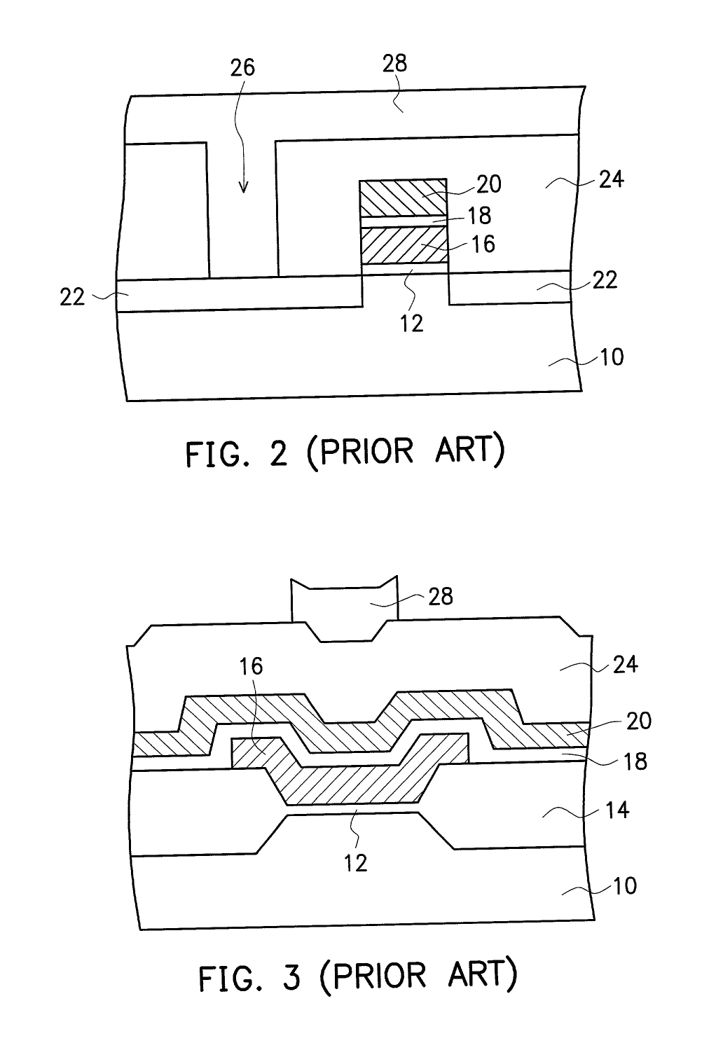

### DETAILED DESCRIPTION OF THE PREFERRED EMBODIMENT

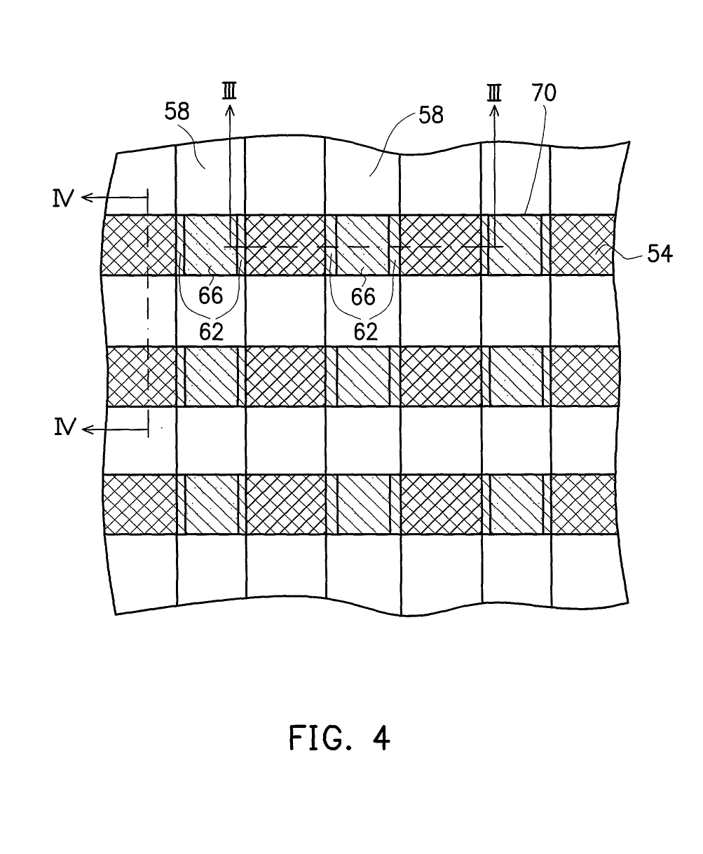

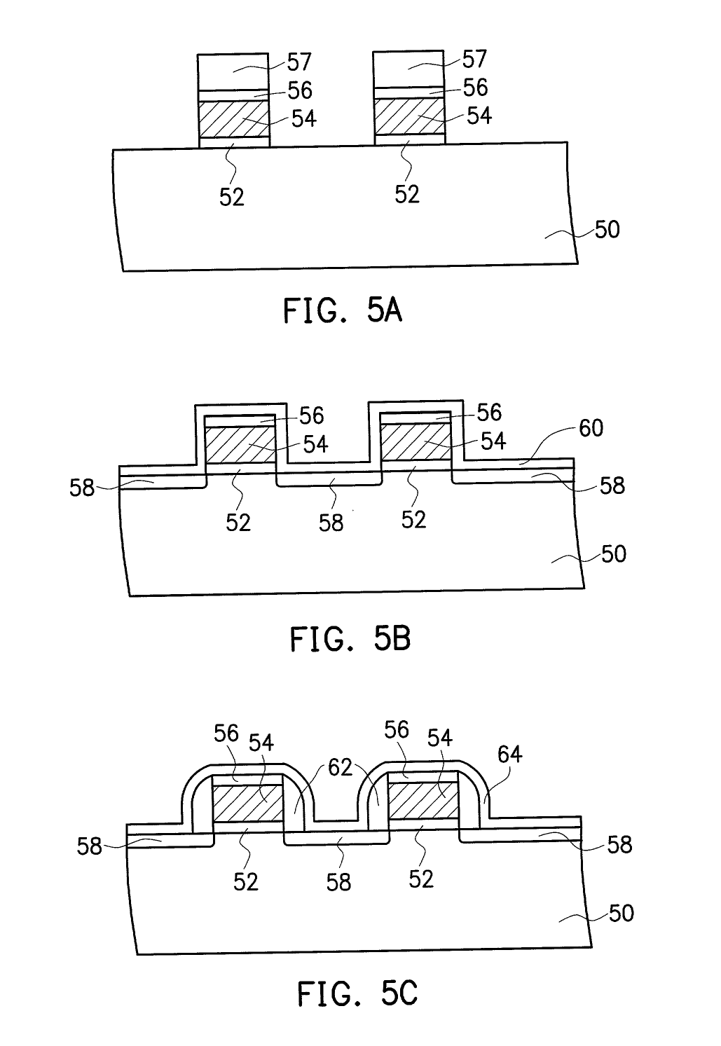

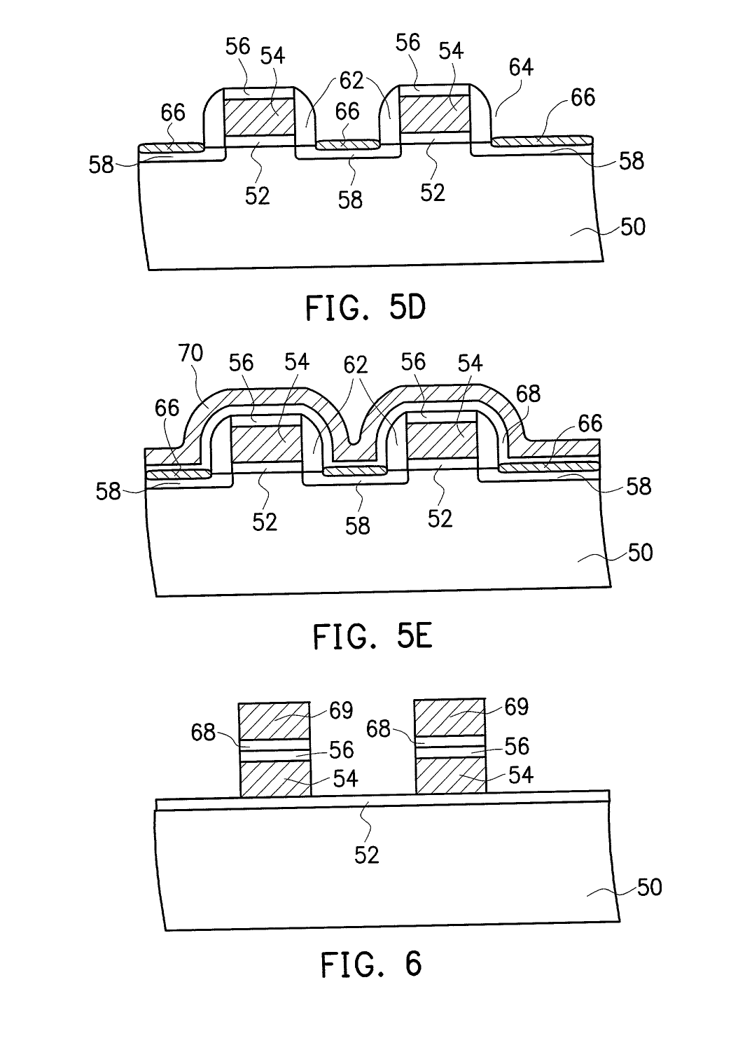

FIG. 4 is a schematic, top view showing a one time programmable read only memory according to a preferred embodiment of the invention. FIGS. 5A-5E are schematic, cross-sectional views showing a method for manufacturing the one time programmable read only memory of FIG. 4 along a dashed line III-III.

Referring to FIG. 5A, a substrate 50 is provided. A first oxide layer, a polysilicon layer, a second oxide layer (not shown) are formed in order on the substrate 50 by thermal oxidation, low pressure chemical vapor deposition and chemical vapor deposition respectively. A photoresist layer 57 is formed on the second oxide layer by photolithography. Next, the two oxide layers and the polysilicon layer are patterned to form a remaining first oxide layer 52, a first polysilicon layer 54 and a remaining second oxide layer 56.

Referring to FIG. 5B, ion implantation is performed with a dopant to form self-aligned, ion-implanted regions 58 in the substrate 50 on both sides of the first polysilicon layer 54 by using the photoresist layer 57 as a mask. After that, the photoresist layer 57 is removed to expose the second oxide layer 56. An annealing process is performed to diffuse the dopant in the ion-implanted regions 58 which serve as buried bit lines. A silicon nitride layer 60 is formed over the substrate 50, covering surfaces of structures including the second oxide layer 56 by, for example, plasma chemical vapor deposition.

Referring to FIG. 5C, silicon nitride spacers 62 are formed on the sidewalls of the first oxide layer 52, the first polysilicon layer 54 and the second oxide layer 56 by etching back the silicon nitride layer 60. A metal layer 64, such as a titanium layer, is formed over the substrate 5), covering surfaces of structures including the substrate 50, the spacers 62 and the second oxide layer 56, by, for example, sputtering.

Referring to FIG. 5D, a rapid thermal process is performed on the metal layer 64 thereby to form a metal silicide layer 66 on the ion-implanted regions 58. For example, if the metal layer 64 is a titanium layer, the metal silicide layer 66 is a titanium silicide layer. Next, a part of the metal layer 66 that does not react to form the metal silicide is removed.

Referring to FIG. 5E, a silicon nitride layer 68 is formed over the substrate 50, covering surfaces of structures including the second oxide layer 56, the spacers 62 and the metal silicide layer 66, by, for example, plasma chemical vapor deposition. Subsequently, a polysilicon layer 70 is formed on the silicon nitride layer 68 by, for example low pressure chemical vapor deposition. Together, the silicon nitride layer 68 and the second oxide layer 56 constitute an inter-metal dielectric layer.

FIG. 6 is a schematic, cross-sectional view of FIG. 4 along a dashed line IV-IV, corresponding to FIG. 5E.

Referring to FIG. 6, the polysilicon layer 70 (FIG. 5E) is patterned to form a second polysilicon layer 69 by conventional photolithography and etching. Then, using the second polysilicon layer 69 as a mask, etching is further performed to form a complete gate structure consisting of the first polysilicon layer 54, the second oxide layer 56, the silicon nitride layer 68 and the second polysilicon layer 69, wherein the first polysilicon layer 54 and the second polysilicon layer 69 serve as a floating gate and a control gate, respectively.

Additionally, subsequent processes performed to completely form the programmable read only memory are well known by those skilled in the art, and will not be further described hereinafter.

As can be clearly seen from the above, the ion-implanted regions 58 (buried bit lines) can be self-aligned with the first polysilicon layer 54 (floating gate) while the first polysilicon layer 54 can be self-aligned with the second polysilicon layer 69 (control gate).

In summary, a feature of the one time programmable read only memory according to the invention is that the ion-implanted regions 58 (buried bit lines) can be self-aligned with the first polysilicon layer 54 (floating gate). In addition, the contact resistance of the bit lines is lowered to approximately 1/10-1/100 of that in the prior art. Accordingly, the performance of the one time programmable read only memory is enhanced. Moreover, since it is unnecessary to form contact windows and metal layers therein, there is no problem with reflection interference caused by the metal layers.

Furthermore, there is no need to form field oxide layers. Therefore, the one time programmable read only memory manufactured in accordance with the invention can have a small size and a better planarity.

While the invention has been described by way of example and in terms of the preferred embodiment, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A one time programmable read only memory comprising:
a substrate;
a first oxide layer formed on the substrate;
a floating gate formed on the first oxide layer;
an inter-metal dielectric layer formed on the floating gate;
ion-implanted regions formed in the substrate on both sides of the floating gate;
a metal suicide layer formed on the substrate just above the ion-implanted regions;
spacers formed on both sidewalls of the floating gate; and
a control gate formed on the inter-metal dielectric layer.

2. The one time programmable read only memory as set forth in claim 1, wherein the ion-implanted regions serves as a buried bit layer.

3. The one time programmable read only memory as set forth in claim 1, wherein the spacers are silicon nitride spacers.

4. The one time programmable read only memory as set forth in claim 1, wherein the metal silicide layer is a titanium silicide layer.

5. The one time programmable read only memory as set forth in claim 1, wherein the control gate comprises a silicon nitride layer formed on the inter-metal dielectric layer.

6. The one time programmable read only memory as set forth in claim 1, wherein the inter-metal dielectric layer comprises a second oxide layer formed on the floating gate and a silicon nitride layer formed on the second oxide layer.

7. The one time programmable read only memory as set forth in claim 6, wherein the silicon nitride layer further covers the metal silicide layer.

8. The one time programmable read only memory as set forth in claim 1, wherein the spacers further cover the sidewalls of the first oxide layer and the second oxide layer.

9. A one time programmable read only memory comprising:
a substrate;
a plurality of first oxide layers formed on the substrate;
a plurality of floating gates formed on the first oxide layers, respectively;
a plurality of inter-metal dielectric layers formed on the floating gates, respectively;
a plurality of ion-implanted regions formed in the substrate on both sides of floating gates;
a plurality of metal suicide layers formed on the substrate just above the ion-implanted regions;
a plurality of spacers formed on the sidewalls of the floating gates; and
a plurality of control gates formed on the inter-metal dielectric layers, respectively.

10. The one time programmable read only memory as set forth in claim 9, wherein the ion-implanted regions are a plurality of buried bit lines.

11. The one time programmable read only memory as set forth in claim 9, wherein the spacers are silicon nitride spacers.

12. The one time programmable read only memory as set forth in claim 9, wherein the metal silicide layers are titanium silicide layers.

13. The one time programmable read only memory as set forth in claim 9, wherein each inter-metal dielectric layer comprises a second oxide layer formed on a corresponding floating gate and a silicon nitride layer formed on the second oxide layer.

14. The one time programmable read only memory as set forth in claim 13, wherein the silicon nitride layer further covers adjacent metal silicide layers.

15. The one time programmable read only memory as set forth in claim 13, wherein the spacers further cover the sidewalls of the first oxide layers and the second oxide layers.

16. The one time programmable read only memory as set forth in claim 13, wherein the control gates further cover the silicon nitride layers.
